(19) United States
(12) Patent Application Publication
(10) Pub. No.: US 2009/0212876 A1
(43) Pub. Date: Aug. 27, 2009

(54) OSCILLATOR CONTROLLING APPARATUS

(75) Inventor: Hiroyuki KOBAYASHI, Yokohama-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/390,826

(22) Filed: Feb. 23, 2009

(30) Foreign Application Priority Data
Feb. 25, 2008 (JP) 2008-042876

(51) Int. Cl. H03L 7/085

(52) U.S. Cl. 331/1 A

(57) ABSTRACT

An oscillation controlling apparatus has a digitally-controlled oscillator configured to output an oscillating signal with an oscillation frequency according to an oscillator adjustment signal, and include a variable current source which supplies operation current based on an operation current control signal, a phase difference calculating unit configured to calculate a phase difference between the oscillating signal and a reference signal to output a phase difference signal, a filter configured to smooth a difference between a phase instruction signal setting the oscillation frequency of the digitally-controlled oscillator and the phase difference signal to output the oscillator adjustment signal, and a controlling unit configured to obtain the oscillator adjustment signal, output the operation current control signal so as to vary a value of the operation current, extract the value of the operation current at which the oscillator adjustment signal becomes the maximum value, and output the operation current control signal so that the operation current supplied by the variable current source becomes the extracted value.

### CROSS REFERENCE TO RELATED APPLICATIONS

This application is based upon and claims the benefit of priority from the Japanese Patent Application No. 2008-42876, filed on Feb. 25, 2008, the entire contents of which are incorporated herein by reference.

### BACKGROUND OF THE INVENTION

The present invention relates to an oscillator controlling apparatus.

In recent years, there have been demands in analog design for utilization of the same processes as in digital devices, and the operation at lower voltage. Thus, it has become difficult to obtain the same stability as conventional analog devices. A voltage controlled oscillator (VCO), which is one of circuit components of a RF (Radio Frequency) communication apparatus, requires stable characteristics against process and environmental variations. It is particularly important to realize stable phase noise characteristics to guarantee the communication characteristics.

With the control voltage being fixed, the oscillation frequency of the voltage controlled oscillator varies with the variation in operation current. It has been known that, when the phase noise characteristics are concurrently observed in this case, a relation exists such that phase noise becomes the minimum at a current value at which the oscillation frequency becomes the maximum.

An operation current adjusting apparatus has been proposed, in which by utilizing such a relation, the oscillation frequency of the voltage controlled oscillator is detected by using a counter or the like while varying the operation current, a value of the operation current is extracted when the oscillation frequency takes the maximum value, and this extracted value is set to the operation current in actual use (for example, refer to Japanese Patent Laid-Open No. 2007-251228).

However, a long detection time is needed to achieve the necessary frequency resolution of a detector. Thus, there has been a problem that a long time is needed to obtain the stable phase noise characteristics.

### SUMMARY OF THE INVENTION

According to one aspect of the present invention, there is provided an oscillation controlling apparatus comprising:

a digitally-controlled oscillator configured to output an oscillating signal with an oscillation frequency according to an oscillator adjustment signal, and include a variable current source which supplies operation current based on an operation current control signal;

a phase difference calculating unit configured to calculate a phase difference between the oscillating signal and a reference signal to output a phase difference signal;

a filter configured to smooth a difference between a phase instruction signal setting the oscillation frequency of the digitally-controlled oscillator and the phase difference signal to output the oscillator adjustment signal; and

a controlling unit configured to obtain the oscillator adjustment signal, output the operation current control signal so as to vary a value of the operation current, extract the value of the operation current at which the oscillator adjustment signal becomes the maximum value, and output the operation current control signal so that the operation current supplied by the variable current source becomes the extracted value.

According to one aspect of the present invention, there is provided an oscillation controlling apparatus comprising:

a digitally-controlled oscillator configured to output an oscillating signal with an oscillation frequency according to an oscillator adjustment signal, and include a variable current source which supplies operation current based on an operation current control signal;

a phase difference calculating unit configured to calculate a phase difference between the oscillating signal and a reference signal to output a phase difference signal;

a filter configured to smooth a difference between a phase instruction signal setting the oscillation frequency of the digitally-controlled oscillator and the phase difference signal to output the oscillator adjustment signal; and

a controlling unit configured to obtain the oscillator adjustment signal, output the operation current control signal so as to vary a value of the operation current, extract the value of the operation current at which the oscillator adjustment signal becomes the minimum value, and output the operation current control signal so that the operation current supplied by the variable current source becomes the extracted value.

### BRIEF DESCRIPTION OF THE DRAWINGS

FIG. 1 is a schematic diagram of an oscillator controlling apparatus according to an embodiment of the present invention;

FIG. 2 is a schematic diagram of a DCO;

FIG. 3 is a graph illustrating a relation between an OTW value and an oscillation frequency of the DCO;

FIG. 4 is a graph illustrating a relation between bias current and the oscillation frequency of the DCO, and a relation between the bias current and phase noise;

FIG. 5 is a graph illustrating a relation between the bias current of the DCO and the OTW value in an ADPLL, and a relation between the bias current and the phase noise;

FIG. 6 is a schematic diagram of a controlling unit according to the embodiment; and

FIG. 7 is a graph illustrating another example of the relation between the bias current of the DCO and the OTW value in the ADPLL.

### DESCRIPTION OF THE EMBODIMENTS

An oscillator controlling apparatus according to an embodiment of the present invention will be described below based on the drawings.

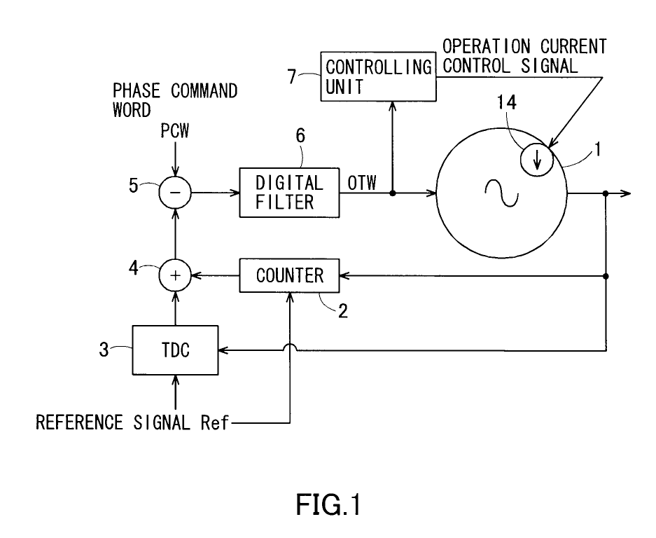

FIG. 1 schematically illustrates a configuration of the oscillator controlling apparatus according to the embodiment of the present invention. The oscillator controlling apparatus includes a digitally-controlled oscillator (hereinafter, DCO) 1, a counter 2, a TDC (Time to Digital Converter) 3, an adder 4, a subtracter 5, a digital filter 6, and a controlling unit 7, and is configured as an ADPLL (All Digital Phased Locked Loop). The DCO 1 is an oscillator whose oscillation frequency can be discretely controlled by an external control signal.

The counter 2 calculates a phase difference between an output (an oscillating signal) of the DCO 1 and a reference signal Ref. The TDC 3 is a time measuring device which can provide a digital representation of the phase difference between the output of the DCO 1 and the reference signal Ref with finer resolution than that of the counter 2. The adder 4 adds an output of the counter 2 and an output of the TDC 3, and outputs an added value to the subtracter 5. The phase difference between the oscillation signal outputted from the DCO 1 and the reference signal Ref is calculated by the counter 2, the TDC 3, and the adder 4.

The subtracter 5 calculates a difference between the added value outputted from the adder 4 and a phase control value PCW (Phase Command Word), and outputs the calculated difference value to the digital filter 6. The phase control value PCW is an amount of phase change per reference frequency.

The digital filter 6 smoothes the inputted difference value, and outputs a signal OTW (Oscillator Tuning Word) for controlling the oscillation frequency of the DCO 1. The signal OTW is provided to the DCO 1 and the controlling unit 7. The controlling unit 7 outputs an operation current control signal to a variable current source 14 included in the DCO 1. The variable current source 14 supplies the DCO 1 with operation current (bias current) according to the operation current control signal.

When the oscillation frequency of the DCO 1 becomes larger (or smaller) than a value set by the phase control value PCW, the controlling signal OTW for decreasing (or increasing) the oscillation frequency based on the difference value calculated by the subtracter 5 is outputted from digital filter 6 to the DCO 1. Thereby, the oscillation frequency of the DCO 1 is controlled to be constant.

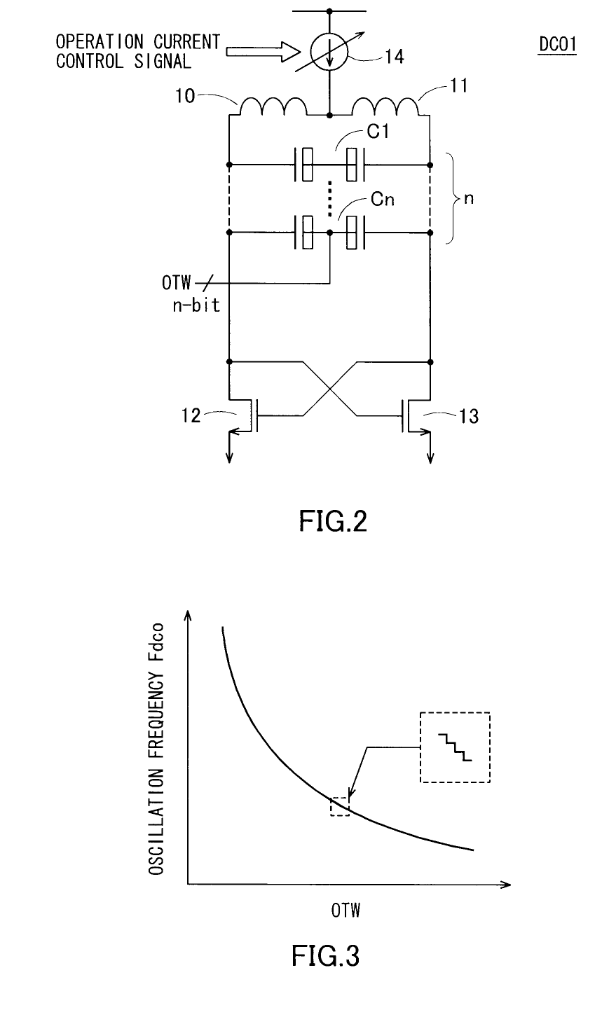

FIG. 2 illustrates an exemplary configuration of the DCO 1. The DCO 1 includes inductors 10 and 11, “n” (“n” is an integer, and two or more) pieces of capacitors C1 to Cn, nMOS transistors 12 and 13, and the variable current source 14. The variable current source 14 is supplied with the operation current control signal outputted from the controlling unit 7, and supplies the operation current (bias current) accordingly.

The capacitors C1 to Cn are MOS-type capacitors connected in parallel. A value of each bit of the n-bit signal OTW controls back gate voltage, source voltage, and drain voltage of each of the capacitors C1 to Cn.

For example, when one bit of the signal OTW is “1”, the back gate voltage, source voltage, and drain voltage of the corresponding capacitor are increased, and a capacitance value is increased. When one bit of the signal OTW is “0”, the back gate voltage, source voltage, and drain voltage of the corresponding capacitor are decreased, and the capacitance value is decreased. The value of the signal OTW changes combined capacitance values of the capacitors C1 to Cn, and thereby, the oscillation frequency of the DCO 1 can be varied.

FIG. 3 illustrates a relation between a value of the signal OTW and an oscillation frequency Fdco of the DCO 1. When the value of the signal OTW becomes larger, the number of the capacitors having an increased capacitance value is increased, so that the combined capacitance value is increased, while the oscillation frequency Fdco is decreased. As described above, the DCO 1 is an oscillator including the discrete output frequencies which can be controlled by the signal OTW.

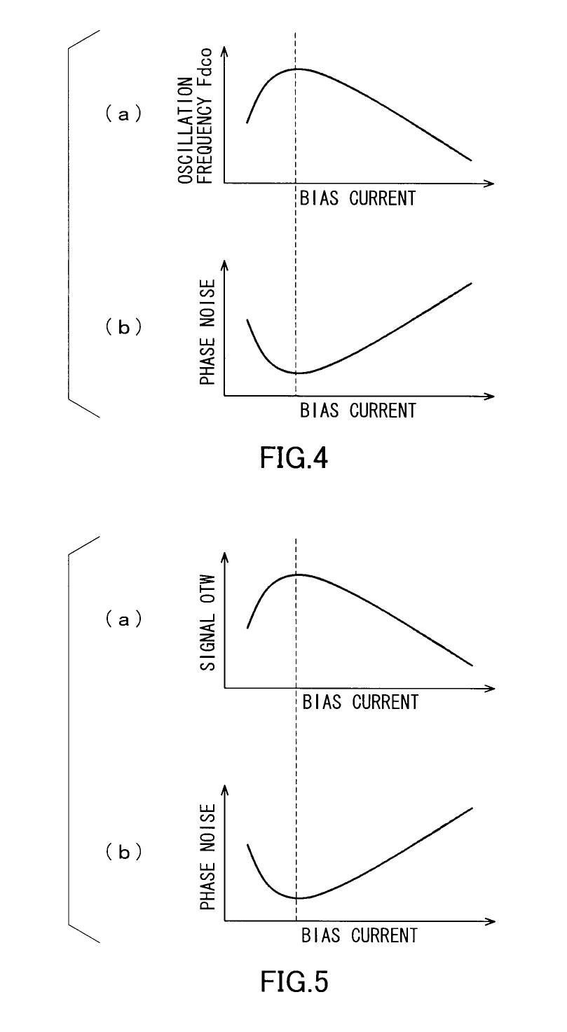

Next, a relation between the bias current and the oscillation frequency of a general DCO, and a relation between the bias current and the phase noise of the general DCO will be described. FIG. 4(a) illustrates the relation between the bias current and the oscillation frequency of the DCO, and FIG. 4(b) illustrates the relation between the bias current and phase noise.

As illustrated in FIG. 4, when the bias current is varied, the oscillation frequency varies. As can be seen, when the phase noise characteristics are concurrently observed in this case, the phase noise becomes the minimum at a current value at which the oscillation frequency becomes the maximum. That is, the phase noise characteristics become most favorable at the current value at which the oscillation frequency becomes the maximum.

Next, in the ADPLL as illustrated in FIG. 1, the relation between the bias current of the DCO 1 and the value of the signal OTW, and the relation between the bias current and the phase noise of the DCO 1 will be described. FIG. 5(a) illustrates the relation between the bias current of the DCO 1 and the value of the signal OTW provided to the DCO 1, and FIG. 5(b) illustrates the relation between the bias current and the phase noise.

As described above, in the DCO 1 of the ADPLL, the oscillation frequency is controlled to be constant. Thus, the value of the signal OTW varies so that the variation in the oscillation frequency along with the variation in the bias current is suppressed (corrected).

For example, when the oscillation frequency is increased along with the variation in the bias current, the value of the signal OTW varies so that the oscillation frequency is decreased. That is, the value of the signal OTW is increased. When the oscillation frequency is decreased along with the variation in the bias current, the value of the signal OTW varies so that the oscillation frequency is increased. That is, the value of the signal OTW is decreased.

Thus, as illustrated in FIG. 5(a), when the bias current is a value at which the oscillation frequency of the DCO 1 becomes the maximum value, the value of the signal OTW becomes the maximum value to cause the oscillation frequency to be constant. As can be seen, when the phase noise characteristics are concurrently observed in this case, the phase noise becomes the minimum at a current value at which the value of the signal OTW becomes the maximum. That is, the phase noise characteristics become most favorable at the current value at which the value of the signal OTW becomes the maximum. The value of the signal OTW includes an enough amount of variation for the variation in the bias current.

In the present embodiment, by utilizing this relation between the bias current and the phase noise, the controlling unit 7 observes the variation in the value of the signal OTW because of the bias current to detect the optimum bias current.

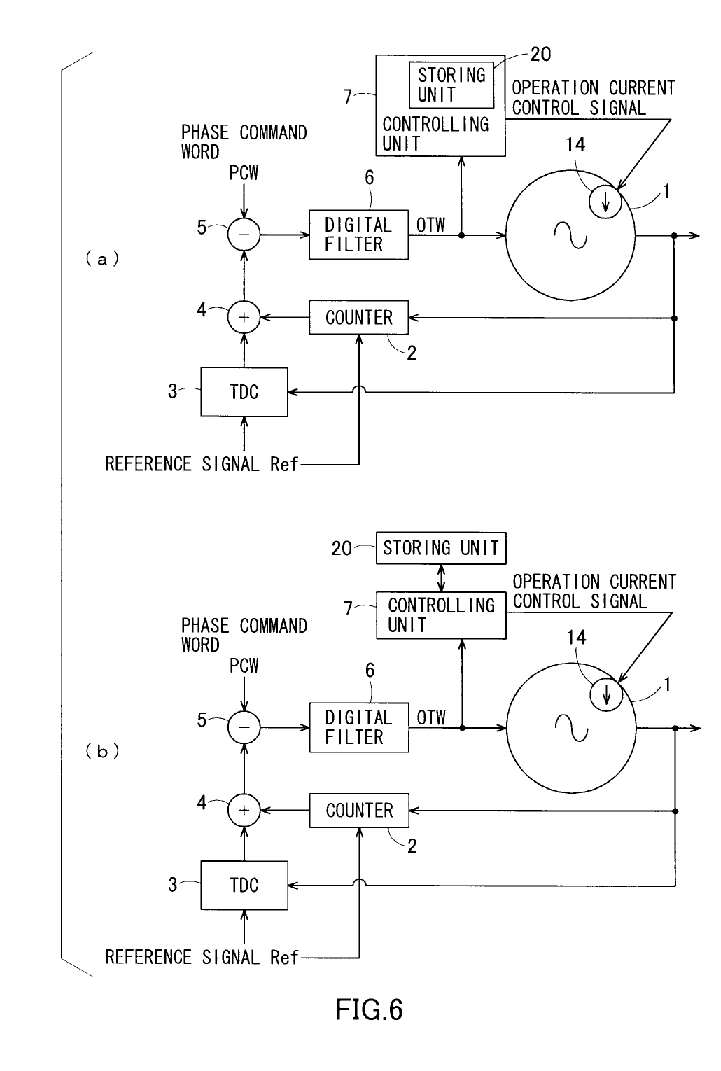

An operation of the controlling unit 7 will be described. The controlling unit 7 sets the bias current of the DCO 1 to a sufficiently large value (for example, an upper limit value) when the operation is started, such as when the power is turned on. The controlling unit 7 detects the value of the signal OTW of this case to store the detected value. The controlling unit 7 may detect the value of the signal OTW several times (for a predetermined time) to store the average value. As illustrated in FIG. 6(a), a storing unit 20, which stores the value of the signal OTW, may be provided inside the controlling unit 7, or, as illustrated in FIG. 6(b), the storing unit 20 may be provided outside the controlling unit 7.

Next, the controlling unit 7 decreases the bias current by a predetermined value, and detects the value of the signal OTW of this case to store the detected value. The controlling unit 7 repeats such an operation until the bias current becomes a sufficiently small value (for example, a lower limit value).

Thereby, the bias current and the value of the signal OTW, which are illustrated in FIG. 5(a), are obtained. As illustrated above, the phase noise characteristics become most favorable at the bias current at which the value of the signal OTW becomes the maximum.

Thus, the controlling unit 7 detects a bias current value at which the value of the signal OTW becomes the maximum to store the detected bias current value, and sets the stored bias current value to the variable current source 14 of the DCO 1 when this oscillation controlling apparatus is actually used. The value of the signal OTW has a resolution on the order of a kilohertz, and the maximum value of the signal OTW can be obtained in a short time, so that the stable phase noise characteristics can be quickly obtained.

As described above, in the oscillation controlling apparatus of the present embodiment, the stable phase noise characteristics can be quickly obtained. The value of the signal OTW is utilized, which is inherently included in the ADPLL, so that the oscillation controlling apparatus can be implemented without significantly occupying the area.

While the controlling unit 7 varies the bias current from the sufficiently large value to the sufficiently small value in the above embodiment, the controlling unit 7 may terminate sweeping the bias current at a time point when the detected value of the signal OTW is changed from increase to decrease.

While the controlling unit 7 detects the value of the signal OTW while gradually decreasing the bias current in the above embodiment, the controlling unit 7 may detect the value of the signal OTW while gradually increasing the bias current. In this case, an initial setting value of the bias current is set to a value at which the DCO 1 can oscillate.

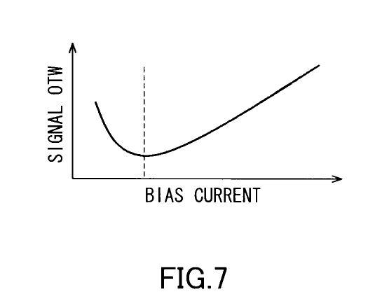

The above embodiment has been described by using an example in which the bias current of the DCO 1 and the value of the signal OTW are in a relation shown as an upward convex curve as illustrated in FIG. 5(a). However, when they are in a relation shown as a downward convex curve as illustrated in FIG. 7, the controlling unit 7 detects the minimum value of the signal OTW, and sets the bias current value of that moment to the variable current source 14 of the DCO 1 when the oscillation controlling apparatus is actually used.

For example, such a case corresponds to a case that the oscillation frequency becomes higher as the value of the signal OTW is larger, and a case that the relation between the bias current and the oscillation frequency is shown as a downward convex curve as contrary to FIG. 4(a).

The oscillation controlling apparatus according to the above embodiment can be used for a wireless communication apparatus such as a mobile phone.

What is claimed is:

1. An oscillation controlling apparatus comprising:
a digitally-controlled oscillator configured to output an oscillating signal with an oscillation frequency according to an oscillator adjustment signal, and include a variable current source which supplies operation current based on an operation current control signal;
a phase difference calculating unit configured to calculate a phase difference between the oscillating signal and a reference signal to output a phase difference signal;
a filter configured to smooth a difference between a phase instruction signal setting the oscillation frequency of the digitally-controlled oscillator and the phase difference signal to output the oscillator adjustment signal; and
a controlling unit configured to obtain the oscillator adjustment signal, output the operation current control signal so as to vary a value of the operation current, extract the value of the operation current at which the oscillator adjustment signal becomes the maximum value, and output the operation current control signal so that the operation current supplied by the variable current source becomes the extracted value.

2. The oscillation controlling apparatus according to claim 1,
wherein the controlling unit sequentially varies the value of the operation current, sequentially obtains and stores the oscillator adjustment signal corresponding to each operation current, extracts the value of the operation current corresponding to the maximum value of the stored oscillator adjustment signals, and sets the operation current control signal so that the operation current becomes the extracted value.

3. The oscillation controlling apparatus according to claim 2,
wherein the controlling unit further includes a storing unit storing the oscillator adjustment signal corresponding to each operation current.

4. The oscillation controlling apparatus according to claim 1,
wherein the digitally-controlled oscillator outputs the oscillating signal with the lower oscillation frequency as the value of the oscillator adjustment signal is larger.

5. The oscillation controlling apparatus according to claim 1,
wherein the controlling unit measures an average value of the oscillator adjustment signal during a predetermined time.

6. An oscillation controlling apparatus comprising:
a digitally-controlled oscillator configured to output an oscillating signal with an oscillation frequency according to an oscillator adjustment signal, and include a variable current source which supplies operation current based on an operation current control signal;
a phase difference calculating unit configured to calculate a phase difference between the oscillating signal and a reference signal to output a phase difference signal;
a filter configured to smooth a difference between a phase instruction signal setting the oscillation frequency of the digitally-controlled oscillator and the phase difference signal to output the oscillator adjustment signal; and
a controlling unit configured to obtain the oscillator adjustment signal, output the operation current control signal so as to vary a value of the operation current, extract the value of the operation current at which the oscillator adjustment signal becomes the minimum value, and output the operation current control signal so that the operation current supplied by the variable current source becomes the extracted value.

7. The oscillation controlling apparatus according to claim 6,
wherein the controlling unit sequentially varies the value of the operation current, sequentially obtains and stores the oscillator adjustment signal corresponding to each operation current, extracts the value of the operation current corresponding to the minimum value of the stored oscillator adjustment signals, and sets the operation current control signal so that the operation current becomes the extracted value.

8. The oscillation controlling apparatus according to claim 7,
wherein the controlling unit further includes a storing unit storing the oscillator adjustment signal corresponding to each operation current.

9. The oscillation controlling apparatus according to claim 6,
wherein the digitally-controlled oscillator outputs the oscillating signal with the higher oscillation frequency as the value of the oscillator adjustment signal is larger.

10. The oscillation controlling apparatus according to claim 6,
wherein the controlling unit measures an average value of the oscillator adjustment signal during a predetermined time.
